(19) United States
(12) Patent Application Publication
(10) Pub. No.: US 2025/0234647 A1
(43) Pub. Date: Jul. 17, 2025

(54) ARRAY SUBSTRATE AND DISPLAY PANEL

(71) Applicant: WUHAN CHINA STAR OPTOELECTRONICS SEMICONDUCTOR DISPLAY TECHNOLOGY CO., LTD., Wuhan, Hubei (CN)

(72) Inventors: Liang YE, Wuhan, Hubei (CN); Cheng WANG, Wuhan, Hubei (CN)

(73) Assignee: WUHAN CHINA STAR OPTOELECTRONICS SEMICONDUCTOR DISPLAY TECHNOLOGY CO., LTD., Wuhan, Hubei (CN)

(21) Appl. No.: 18/701,941

(22) PCT Filed: Dec. 21, 2023
(86) PCT No.: PCT/CN2023/140619

§ 371 Date: Apr. 17, 2024

(30) Foreign Application Priority Data
Dec. 7, 2023 (CN) 202311683942.X

(51) Int. Cl. H10D 86/40; H10D 86/60

(52) U.S. Cl. CPC H10D 86/441; H10D 86/423; H10D 86/481; H10D 86/60

(57) ABSTRACT

An array substrate and a display panel. In the array substrate, orthographic projections of a first scan line connected to a first oxide transistor and a second scan line connected to a second oxide transistor on the substrate are separated from an orthographic projection of a first connection line connected between the first oxide transistor and a first transistor, and an orthographic projection of a second connection line connected between the first oxide transistor and the second oxide transistor on the substrate, thereby solving a problem of lateral crosstalk.

### FIELD OF INVENTION

The present disclosure relates to a field of display technology, specifically relates to an array substrate and a display panel.

### BACKGROUND

Flat display panels have many advantages such as thin body, power saving, and no radiation, and have been widely used. Current flat display panels mainly include liquid crystal display (LCD) panels and organic light emitting diode (OLED) panels. Thin film transistors (TFTs) are an important component of flat display panels. TFTs may be formed on glass or plastic substrates, and are often used as switching components and driving components in flat display panels such as LCD panels and OLED panels.

Currently, most OLED panels are low temperature poly-silicon (LTPS) display panels. LTPS display panels have advantages of high resolution, high response speed, high brightness, and high aperture ratio, but have disadvantages of high production costs and high power consumption. In view of this, with development of display technology, low temperature polycrystalline oxide (LTPO) display panels have emerged. LTPO display panels are obtained by combining LTPS display panel technology and oxide display panel technology, so that LTPO display panels includes LTPS thin film transistors and oxide thin film transistors. LTPO display panels not only have the advantages of high resolution, high response speed, high brightness, and high aperture ratio of LTPS display panels, but also have advantages of low production cost and low power consumption.

However, in a current LTPO display panel, there is a large coupling capacitance between a scan line of an oxide thin film transistor and a connection line connecting a Q point in a pixel circuit, causing serious lateral crosstalk in the LTPO display panel.

### SUMMARY

The present disclosure provides an array substrate and a display panel, which solve a technical problem of serious lateral crosstalk in current LTPO display panels.

In order to solve the above problem, the present disclosure provides the following technical solutions.

In a first aspect, the present disclosure provides an array substrate, which comprises a substrate and a plurality of sub-pixels arranged in an array on the substrate. Each of the sub-pixels comprises a first transistor, and a first oxide transistor and a second oxide transistor connected to the first transistor. A drain electrode of the first oxide transistor is connected to a gate electrode of the first transistor, and is connected to a source electrode of the second oxide transistor. A drain electrode of the second oxide transistor is connected to a drain electrode of the first transistor.

The array substrate further comprises:
a first connection line connected between the drain electrode of the first oxide transistor and the gate electrode of the first transistor;
a second connection line connected between the drain electrode of the first oxide transistor and the source electrode of the second oxide transistor;
a first scan line connected to a gate electrode of the first oxide transistor; and
a second scan line connected to a gate electrode of the second oxide transistor.

An orthographic projection of the first scan line on the substrate is separated from an orthographic projection of the first connection line and the second connection line on the substrate. An orthographic projection of the second scan line on the substrate is separated from the orthographic projection of the first connection line and the second connection line on the substrate.

In a second aspect, the present disclosure further provides a display panel that includes an array substrate. The array substrate includes a substrate and a plurality of sub-pixels arranged in an array on the substrate. Each of the sub-pixels comprises a first transistor, and a first oxide transistor and a second oxide transistor connected to the first transistor. A drain electrode of the first oxide transistor is connected to a gate electrode of the first transistor, and is connected to a source electrode of the second oxide transistor. A drain electrode of the second oxide transistor is connected to a drain electrode of the first transistor.

The array substrate further comprises:
a first connection line connected between the drain electrode of the first oxide transistor and the gate electrode of the first transistor;
a second connection line connected between the drain electrode of the first oxide transistor and the source electrode of the second oxide transistor;
a first scan line connected to a gate electrode of the first oxide transistor; and
a second scan line connected to a gate electrode of the second oxide transistor.

An orthographic projection of the first scan line on the substrate is separated from an orthographic projection of the first connection line and the second connection line on the substrate. An orthographic projection of the second scan line on the substrate is separated from the orthographic projection of the first connection line and the second connection line on the substrate.

### BRIEF DESCRIPTION OF DRAWINGS

To describe the technical solutions in the embodiments of this application more clearly, the following briefly introduces the accompanying drawings required for describing the embodiments. Apparently, the accompanying drawings in the following description show merely some embodiments of this application, and a person of ordinary skill in the art may still derive other drawings from these accompanying drawings without creative efforts.

FIG. 1 is a schematic diagram of a pixel circuit of a sub-pixel in a current LTPO display panel.

FIG. 2 is a schematic plan view of a sub-pixel in a current LTPO display panel.

FIG. 3 is a schematic plan view of the sub-pixel in FIG. 2 after removing some vertical traces.

FIG. 4 is a schematic diagram of an arrangement of pixels in an array substrate according to an embodiment of the present disclosure.

FIG. 5 is a schematic diagram of a pixel circuit of a sub-pixel in FIG. 3.

FIG. 6 is a schematic plan view of the sub-pixel in FIG. 3.

FIG. 7 is a schematic plan view of the sub-pixel in FIG. 6 after removing a first data line and a first power line.

FIG. 8 is a schematic partial plan view of a second metal layer, a third metal layer, and a second semiconductor layer in FIG. 7.

FIG. 9 is a schematic diagram of a film structure of some transistors in FIG. 7.

### DETAILED DESCRIPTION OF PRESENT DISCLOSURE

The descriptions of each of the following embodiments are illustrations attached with reference to the specific embodiments that can be used to be implemented in the present application. The directional terms mentioned in the present application, such as “upper,” “lower,” “front,” “back,” “left,” “right,” “inner,” “outer,” and “lateral,” etc., are only directions with reference to the additional schema. Therefore, the directional terms used are intended to illustrate and understand the application and not to limit it. In the diagram, structurally similar elements are represented by the same designation. In the drawings, the thickness of some layers and areas is exaggerated for clarity and ease of description. That is, the dimensions and thicknesses of each component shown in the drawings are arbitrary, but the present application is not limited to this.

In a current LTPO display panel, there is a large coupling capacitance between a scan line of an oxide thin film transistor and a connection line connecting a Q point in a pixel circuit, resulting in serious lateral crosstalk in the LTPO display panel. The inventor found through research that the main reason is that there is an overlapping area between the scan line of the oxide thin film transistor and the connection line connecting the Q point in the pixel circuit, which results in the large coupling capacitance between the scan line and the connection line.

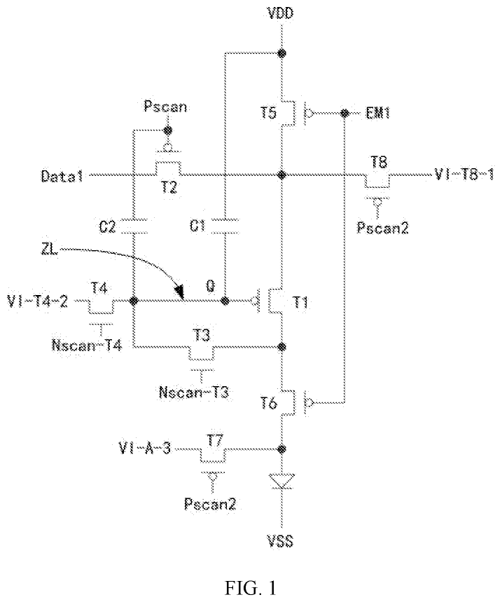

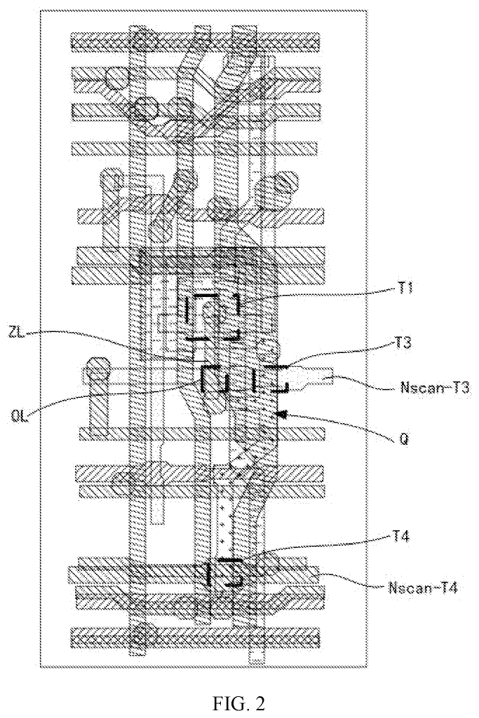

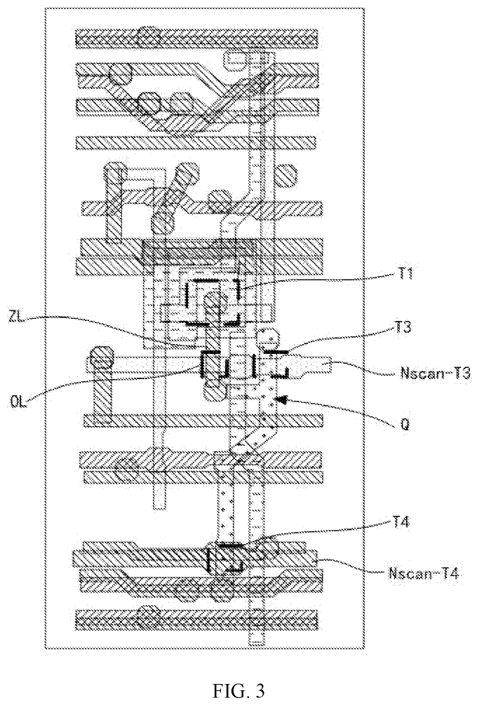

Specifically, please refer to FIG. 1 to FIG. 3. FIG. 1 is a schematic diagram of a pixel circuit of a sub-pixel in a current LTPO display panel. FIG. 2 is a schematic plan view of a sub-pixel in a current LTPO display panel. FIG. 3 is a schematic plan view of the sub-pixel in FIG. 2 after removing some vertical traces. Referring to FIG. 1 to FIG. 3, each sub-pixel includes a first transistor T1, a second transistor T2, a third transistor T3, and a fourth transistor T4. The first transistor T1 and the second transistor T2 are polysilicon transistors. The third transistor T3 and the fourth transistor T4 are oxide transistors. The first transistor T1 is a driving transistor, and the second transistor T2 is a switching transistor.

A drain electrode of the fourth transistor T4 is connected to a gate electrode of the first transistor T1. The drain electrode of the fourth transistor T4 is also connected to a source electrode of the third transistor T3. A gate electrode of the fourth transistor T4 is connected to a first scan line Nscan-T4. The first scan line Nscan-T4 and the gate electrode of the fourth transistor T4 are arranged in a same layer. A drain electrode of the third transistor T3 is connected to a drain electrode of the first transistor T1. A gate electrode of the third transistor T3 is connected to a second scan line Nscan-T3. The gate electrode of the third transistor T3 and the gate electrode of the fourth transistor T4 are arranged in the same layer. The second scan line Nscan-T3 and the gate electrode of the third transistor T3 are arranged in the same layer. A Q point is located among the fourth transistor T4, the first transistor T1, and the third transistor T3. A voltage at the point Q is a voltage on a connection line ZL connecting the fourth transistor T4, the first transistor T1, and the third transistor T3.

Referring to FIG. 2 and FIG. 3, there is an overlapping area OL between the second scan line Nscan-T3 and the connection line ZL connecting the fourth transistor T4 and the first transistor T1, so that there is a large coupling capacitance between the second scan line Nscan-T3 and the connection line ZL. The large coupling capacitance seriously affects a potential at the Q point, causing serious lateral crosstalk in the LTPO display panel.

In view of this, the inventor of the present application further conducted in-depth research, and proposed an array substrate and a display panel to solve the aforementioned problem of lateral crosstalk.

According to the array substrate of an embodiment of the present disclosure, the array substrate includes a substrate and a plurality of sub-pixels arranged in an array on the substrate. Each of the sub-pixels comprises a first transistor, and a first oxide transistor and a second oxide transistor connected to the first transistor. A drain electrode of the first oxide transistor is connected to a gate electrode of the first transistor, and is connected to a source electrode of the second oxide transistor. A drain electrode of the second oxide transistor is connected to a drain electrode of the first transistor.

The array substrate further comprises:
a first connection line connected between the drain electrode of the first oxide transistor and the gate electrode of the first transistor;
a second connection line connected between the drain electrode of the first oxide transistor and the source electrode of the second oxide transistor;
a first scan line connected to a gate electrode of the first oxide transistor;
a second scan line connected to a gate electrode of the second oxide transistor.

An orthographic projection of the first scan line on the substrate is separated from an orthographic projection of the first connection line and the second connection line on the substrate, and an orthographic projection of the second scan line on the substrate is separated from the orthographic projection of the first connection line and the second connection line on the substrate.

According to the array substrate of an embodiment of the present disclosure, the first scan line and the second scan line extend in a first direction and are spaced apart in a second direction, the first direction is different from the second direction, and the first connection line extends in the second direction. The first scan line is located on a side of the first connection line away from the first transistor or the first oxide transistor, and/or the second scan line is located on a side of the first connection line away from the first transistor or the first oxide transistor.

According to the array substrate of an embodiment of the present disclosure, in the second direction, the first transistor and the first oxide transistor are respectively located at both ends of the first connection line, and the first scan line and the second scan line are located on the side of the first connection line away from the first transistor.

According to the array substrate of an embodiment of the present disclosure, in the second direction, the second oxide transistor is located between the first transistor and the first oxide transistor, the second connection line is connected between the first oxide transistor and the second oxide transistor, and the first scan line is located on a side of the second scan line away from the second connection line.

According to the array substrate of an embodiment of the present disclosure, the array substrate further includes a third connection line and a fourth connection line, the third connection line and the fourth connection line extend in the second direction, the third connection line is connected between the first scan line and the gate electrode of the first oxide transistor, the fourth connection line is connected between the second scan line and the gate electrode of the second oxide transistor, an orthographic projection of the third connection line on the substrate is separated from the orthographic projection of the first connection line and the second connection line on the substrate, and an orthographic projection of the fourth connection line on the substrate is separated from the orthographic projection of the first connection line and the second connection line on the substrate.

According to the array substrate of an embodiment of the present disclosure, the gate electrode of the first oxide transistor includes the first gate electrode and the second gate electrode arranged corresponding to each other, the first gate electrode is electrically connected to the second gate electrode, and the third connection line is electrically connected to one of the first gate electrode and the second gate electrode.

The gate electrode of the second oxide transistor includes the third gate electrode and the fourth gate electrode arranged corresponding to each other, the third gate electrode is electrically connected to the fourth gate electrode, and the fourth connection line is electrically connected to one of the third gate electrode and the fourth gate electrode.

According to the array substrate of an embodiment of the present disclosure, the gate electrode of the first oxide transistor includes a first gate electrode and a second gate electrode arranged corresponding to each other, the third connection line includes a first sub-line and a second sub-line, the first sub-line is connected between the first scan line and the first gate electrode, and the second sub-line is connected between the first scan line and the second gate electrode.

The gate electrode of the second oxide transistor includes a third gate electrode and a fourth gate electrode arranged corresponding to each other, the fourth connection line includes a third sub-line and a fourth sub-line, the third sub-line is connected between the second scan line and the third gate electrode, and the fourth sub-line is connected between the second scan line and the fourth gate electrode.

According to the array substrate of an embodiment of the present disclosure, the first gate electrode and the third gate electrode are arranged in the same layer, the second gate electrode and the fourth gate electrode are arranged in the same layer, the first sub-line and the first gate electrode are arranged in the same layer, the second sub-line and the second gate electrode are arranged in the same layer, the third sub-line and the third gate electrode are arranged in the same layer, the fourth sub-line and the fourth gate electrode are arranged in the same layer.

According to the array substrate of an embodiment of the present disclosure, the first scan line, the first gate electrode, and the second gate electrode are arranged in different layers, the second scan line, the third gate electrode, and the fourth gate electrode are arranged in different layers, the first scan line is connected to the first sub-line through a first connection node and is connected to the second sub-line through a second connection node, the second scan line is connected to one of the third sub-line and the fourth sub-line through a third connection node, the third sub-line is connected to the fourth sub-line through a fourth connection node.

According to the array substrate of an embodiment of the present disclosure, the orthotropic projection of the first sub-line on the substrate overlaps at least partially with the orthotropic projection of the second sub-line on the substrate, and the orthotropic projection of the third sub-line on the substrate overlaps at least partially with the orthotropic projection of the fourth sub-line on the substrate.

According to the array substrate of an embodiment of the present disclosure, each subpixel further comprises a second transistor, a third transistor, a fourth transistor, a fifth transistor, a sixth transistor, a seventh transistor, an eighth transistor, a storage capacitor and a compensation capacitor, wherein the third transistor and the fourth transistor are oxide transistors, and the first transistor, the second transistor, the third transistor, the fourth transistor, the fifth transistor, the sixth transistor, the seventh transistor and the eighth transistor are polycrystalline silicon transistors, the fourth transistors are first oxide transistors, and the third transistors are second oxide transistors.

A drain of the fourth transistor is connected with a first electrode plate of the storage capacitor and a first electrode plate of the compensation capacitance, the first electrode plate of the storage capacitor is integrally arranged with the gate of the first transistor, a second electrode plate of the compensation capacitance is connected with a gate of the second transistor, a second electrode plate of the storage capacitor is connected with a source of the fifth transistor, a drain of the fifth transistor is connected with a source of the first transistor, a drain of the first transistor is connected with a drain of the third transistor and a source of the sixth transistor, and a drain of the sixth transistor is connected with a drain of the seventh transistor, a source of the first transistor, a drain of the second transistor and a drain of the fifth transistor are all connected with a drain of the eighth transistor.

According to the array substrate of an embodiment of the present disclosure, the array substrate further comprises:
a first semiconductor layer, arranged on the substrate and comprising an active layer of the first transistor;
a first metal layer, arranged on one side of the first semiconductor layer far away from the substrate, and the first metal layer comprising a gate of the first transistor;
a second metal layer, arranged on one side of the first metal layer far away from the first semiconductor layer;
a second semiconductor layer, arranged on one side of the second metal layer far away from the first metal layer, and the second semiconductor layer comprising an active layer of the first oxide transistor, an active layer of the second oxide transistor, a first connecting wire and a second connecting line;
a third metal layer, arranged on one side of the second semiconductor layer far away from the second metal layer, and a gate of the first oxide transistor and a gate of the second oxide transistor are formed in the third metal layer and the second metal layer;
a fourth metal layer, arranged on one side of the third metal layer far away from the second semiconductor layer, and comprising the first scan line and the second scan line.

In another embodiment of the present disclosure, a display panel is provided. The display panel comprises an array substrate of one of the preceding embodiments.

In the array substrate and the display panel of the present disclosure, the array substrate includes a substrate and a plurality of sub-pixels arranged in an array on the substrate. Each of the sub-pixels comprises a first transistor, and a first oxide transistor and a second oxide transistor connected to the first transistor. The array substrate further comprises: a first connection line connected between the drain electrode of the first oxide transistor and the gate electrode of the first transistor, a second connection line connected between the drain electrode of the first oxide transistor and the source electrode of the second oxide transistor, a first scan line connected to a gate electrode of the first oxide transistor, and a second scan line connected to a gate electrode of the second oxide transistor. An orthographic projection of the first scan line on the substrate is separated from an orthographic projection of the first connection line and the second connection line on the substrate, and an orthographic projection of the second scan line on the substrate is separated from the orthographic projection of the first connection line and the second connection line on the substrate. Since the first scan line and the second scan line do not overlap with a first connection line and a second connection line, coupling capacitances between the first scan line, the second scan line, the first connection line, and the second connection line is reduced, thereby solving the technical problem of serious lateral crosstalk in current LTPO display panels.

The embodiments of the present disclosure are specified below in conjunction with the accompanying drawings.

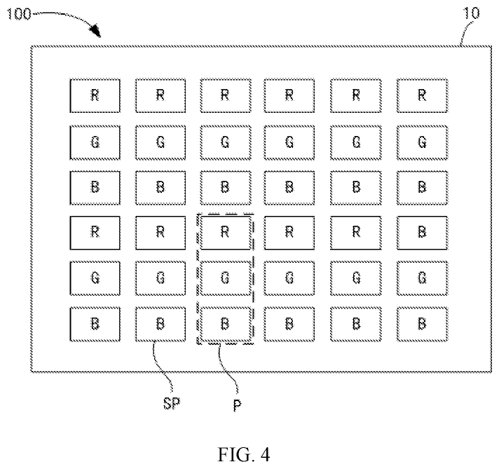

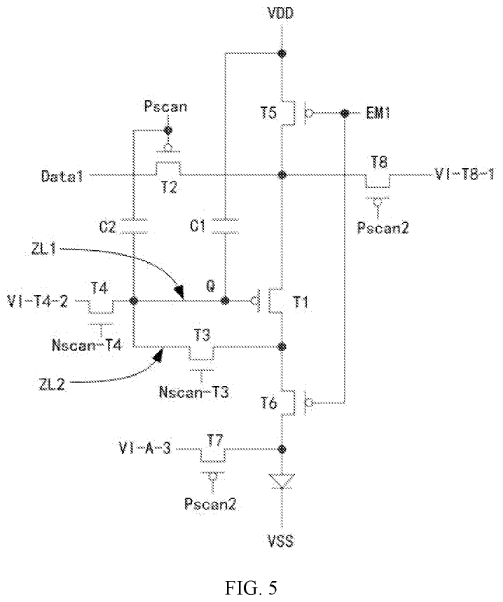

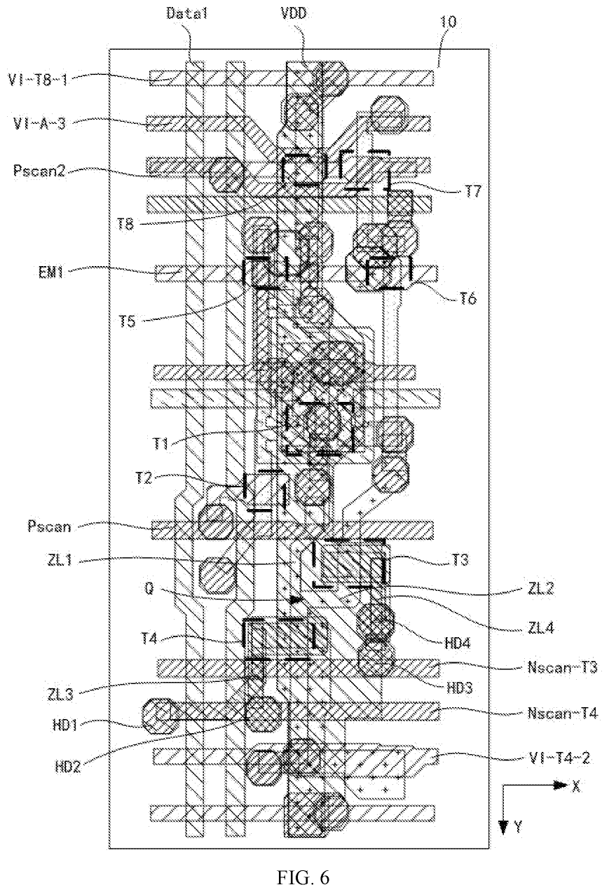

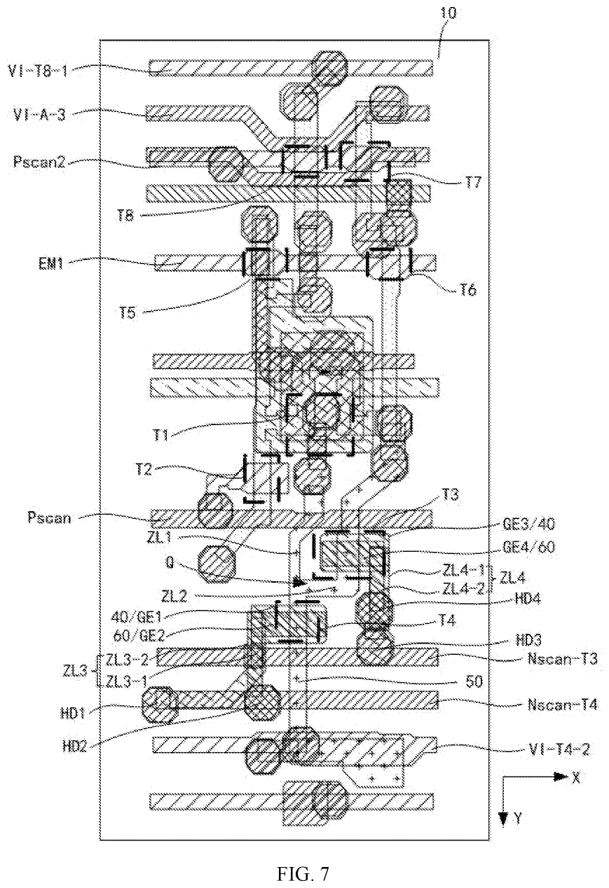

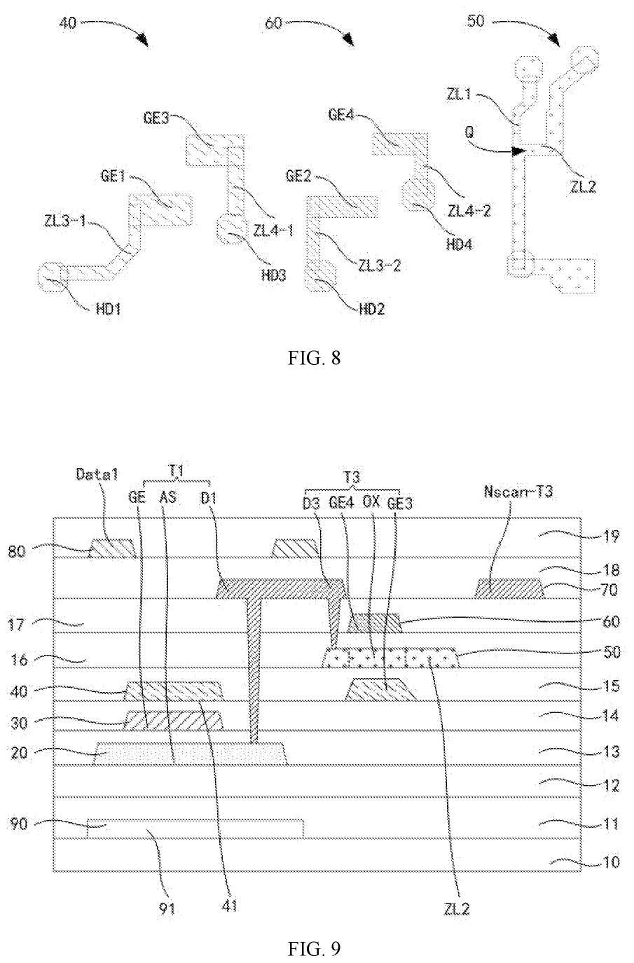

Specifically, please refer to FIG. 4 to FIG. 9. FIG. 4 is a schematic diagram of an arrangement of pixels in an array substrate according to an embodiment of the present disclosure. FIG. 5 is a schematic diagram of a pixel circuit of a sub-pixel in FIG. 3. FIG. 6 is a schematic plan view of the sub-pixel in FIG. 3. FIG. 7 is a schematic plan view of the sub-pixel in FIG. 6 after removing a first data line and a first power line. FIG. 8 is a schematic partial plan view of a second metal layer, a third metal layer, and a second semiconductor layer in FIG. 7. FIG. 9 is a schematic diagram of a film structure of some transistors in FIG. 7. Referring to FIG. 4, the array substrate 100 includes a substrate 10 and a plurality of pixels P arranged in an array on the substrate 10. Each of pixels P includes at least three sub-pixels SP with different colors. For example, three sub-pixels SP with different colors include a red sub-pixel R, a green sub-pixel G, and a blue sub-pixel B. The sub-pixels SP of a same color are arranged into sub-pixel rows. The sub-pixels SP of different colors are arranged into sub-pixel columns.

Referring to FIG. 5, FIG. 6, and FIG. 7, each of the sub-pixels SP includes a first transistor T1, and a first oxide transistor T4 and a second oxide transistor T3 connected to the first transistor T1. A drain electrode of the first oxide transistor T4 is connected to a gate electrode of the first transistor T1, and is connected to a source electrode of the second oxide transistor T3. A drain electrode of the second oxide transistor T3 is connected to a drain electrode of the first transistor T1.

Specifically, each of the sub-pixels SP includes a first transistor T1, a second transistor T2, a third transistor T3, a fourth transistor T4, a fifth transistor T5, a sixth transistor T6, a seventh transistor T7, an eighth transistor T8, a storage capacitor C1, and compensation capacitor C2. The third transistor T3 and the fourth transistor T4 are oxide transistors. The first transistor T1, the second transistor T2, the fifth transistor T5, the sixth transistor T6, the seventh transistor T7, and the eighth transistor T8 are polysilicon transistors. The fourth transistor T4 is the first oxide transistor T4. The third transistor T3 is the second oxide transistor T3. In the following description, the first oxide transistor T4 and the second oxide transistor T3 are used for explanation. It should be noted that the present disclosure only takes an 8T2C pixel circuit as an example to illustrate a structure of each of the sub-pixels SP, but is not limited thereto. The sub-pixels SP of the present disclosure may also have 7T2C, 7T1C, 6T1C, 5T1C, or other pixel circuits.

Referring to FIG. 5, the drain electrode of the first oxide transistor T4 is also connected to a first electrode of the storage capacitor C1 and a first electrode of the compensation capacitor C2. The first electrode of the storage capacitor C1 and the gate electrode of the first transistor T1 are integrally provided. A second electrode of the compensation capacitor C2 is connected to a gate electrode of the second transistor T2. A second electrode of the storage capacitor C1 is connected to a source electrode of the fifth transistor T5. A drain electrode of the fifth transistor T5 is connected to a source electrode of the first transistor T1. The drain electrode of the first transistor T1 is connected to the drain electrode of the second oxide transistor T3 and a source electrode of the sixth transistor T6. A drain electrode of the sixth transistor T6 is connected to a drain electrode of the seventh transistor T7. The source electrode of the first transistor T1, a drain electrode of the second transistor T2, and the drain electrode of the fifth transistor T5 are all connected to a drain electrode of the eighth transistor T8.

Referring to FIG. 5 and FIG. 6, the array substrate 100 further includes a plurality of scan lines and a plurality of signal lines, such as a first scan line Nscan-T4 connected to a gate electrode of the first oxide transistor T4, a first signal line VI-T4-2 connected to a source electrode of the first oxide transistor T4; a second scan line Nscan-T3 connected to a gate electrode of the second oxide transistor T3, a third scan line Pscan connected to the gate electrode of the second transistor T2, a first data line Data1 connected to a source electrode of the second transistor T2, a second signal line EM1 connected to a gate electrode of the fifth transistor T5 and a gate electrode of the sixth transistor T6, a first power line VDD connected to the source electrode of the fifth transistor T5, a fourth scan line Pscan2 connected to a gate electrode of the seventh transistor T7, a third signal line VI-A-3 connected to a source electrode of the seventh transistor T7, a fourth scan line Pscan2 connected to a gate electrode of the eighth transistor T8, and a fourth signal line VI-T8-1 connected to a source electrode of the eighth transistor T8.

Furthermore, the array substrate 100 further includes a first connection line ZL1 and a second connection line ZL2. The first connection line ZL1 is connected between the drain electrode of the first oxide transistor T4 and the gate electrode of the first transistor T1. The second connection line ZL2 is connected between the drain electrode of the first oxide transistor T4 and the source electrode of the second oxide transistor T3. A voltage on the first connection line ZL1 and a voltage on the second connection line ZL2 will affect a potential at a Q point. An orthographic projection of the first scan line Nscan-T4 on the substrate 10 is separated from an orthographic projection of the first connection line ZL1 and the second connection line ZL2 on the substrate 10. An orthographic projection of the second scan line Nscan-T3 on the substrate 10 is separated from the orthographic projection of the first connection line ZL1 and the second connection line ZL2 on the substrate 10. Two orthographic projections are separated from each other, which means that there is no overlap between the two orthographic projections. For example, the orthographic projection of the first scan line Nscan-T4 on the substrate 10 is separated from the orthographic projection of the first connection line ZL1 and the second connection line ZL2 on the substrate 10, which means that there is no overlap between the orthographic projection of the first scan line Nscan-T4 on the substrate 10 and the orthographic projection of the first connection line ZL1 and the second connection line ZL2 on the substrate 10.

The first scan line Nscan-T4 and the second scan line Nscan-T3 do not overlap with the first connection line ZL1 and the second connection line ZL2, so as to reduce coupling capacitances between the first scan line Nscan-T4, the second scan line Nscan-T3, the first connection line ZL1, and the second connection line ZL2, thereby solving the technical problem of serious lateral crosstalk in current LTPO display panels.

The following will describe in detail how to realize that the orthographic projections of the first scan line Nscan-T4 and the second scan line Nscan-T3 are separated from the orthographic projection of the first connection line ZL1 and the second connection line ZL2.

Referring to FIG. 6 and FIG. 7, the first scan line Nscan-T4 and the second scan line Nscan-T3 both extend in a first direction X, and are spaced apart in a second direction Y. The first direction X is different from the second direction Y. For example, the first direction X is a row direction, the second direction Y is a column direction, and the first direction X is perpendicular to the second direction Y. The row direction is an arrangement direction of the sub-pixel rows, and the column direction is an arrangement direction of the sub-pixel columns. Optionally, the third scan line Pscan, the fourth scan line Pscan2, the first signal line VI-T4-2, the second signal line EM1, the third signal line VI-A-3, and the fourth signal line VI-T8-1 all extend in the first direction X, and the first data line Data1 and the first power line VDD both extend in the second direction Y.

The first connection line ZL1 extends in the second direction Y. The first scan line Nscan-T4 is located on a side of the first connection line ZL1 away from the first transistor T1 or the first oxide transistor T4; and/or the second scan line Nscan-T3 is located on a side of the first connection line ZL1 away from the first transistor T1 or the first oxide transistor T4. The present disclosure takes as an example that the first scan line Nscan-T4 and the second scan line Nscan-T3 are located on the side of the first connection line ZL1 away from the first transistor T1.

In the second direction Y, the first transistor T1 and the first oxide transistor T4 are respectively located at both ends of the first connection line ZL1, and the first scan line Nscan-T4 and the second scan line Nscan-T3 are both located on the side of the first connection line ZL1 away from the first transistor T1. Furthermore, in the second direction Y, the second oxide transistor T3 is located between the first transistor T1 and the first oxide transistor T4, and the second connection line ZL2 is connected between the first oxide transistor T4 and the second oxide transistor T3. The second connection line ZL2 first extends in the first direction X, and then extends in the second direction Y. The first scan line Nscan-T4 is located on a side of the second scan line Nscan-T3 away from the second connection line ZL2, which facilitate connection between the first scan line Nscan-T4 and the first oxide transistor T4, and connection between the second scan line Nscan-T3 and the second oxide transistor T3.

The connection between the first scan line Nscan-T4 and the first oxide transistor T4, and the connection between the second scan line Nscan-T3 and the second oxide transistor T3 may be achieved in the following manner.

Referring to FIG. 6 and FIG. 7, the array substrate 100 further includes a third connection line ZL3 and a fourth connection line ZL4. The third connection line ZL3 and the fourth connection line ZL4 both extend in the second direction Y. The third connection line ZL3 is connected between the first scan line Nscan-T4 and the gate electrode of the first oxide transistor T4. The fourth connection line ZL4 is connected between the second scan line Nscan-T3 and the gate electrode of the second oxide transistor T3.

An orthographic projection of the third connection line ZL3 on the substrate 10 is separated from the orthographic projection of the first connection line ZL1 and the second connection line ZL2 on the substrate 10. An orthographic projection of the fourth connection line ZL4 on the substrate 10 is separated from the orthographic projection of the first connection line ZL1 and the second connection line ZL2 on the substrate 10. In this way, the third connection line ZL3 and the fourth connection line ZL4 do not overlap with the first connection line ZL1 and the second connection line ZL2, so as to reduce coupling capacitances between the third connection line ZL3, the fourth connection line ZL4, the first connection line ZL1, and the second connection line ZL2, thereby further solving the technical problem of serious lateral crosstalk in current LTPO display panels.

Referring to FIG. 7 and FIG. 8, the gate electrode of the first oxide transistor T4 includes a first gate electrode GE1 and a second gate electrode GE2 arranged corresponding to each other. The third connection line ZL3 includes a first sub-line ZL3-1 and a second sub-line ZL3-2. The first sub-line ZL3-1 is connected between the first scan line Nscan-T4 and the first gate electrode GE1 of the first oxide transistor T4. The second sub-line ZL3-2 is connected between the first scan line Nscan-T4 and the second gate electrode GE2 of the first oxide transistor T4. The first gate electrode GE1 and the second gate electrode GE2 are arranged in different layers. An orthographic projection of the first gate electrode GE1 on the substrate 10 is within an orthographic projection of the second gate electrode GE2 on the substrate 10. The first sub-line ZL3-1 and the first gate electrode GE1 are arranged in a same layer. The second sub-line ZL3-2 and the second gate electrode GE2 are arranged in a same layer.

The first scan line Nscan-T4 and the first gate electrode GEL and the second gate electrode GE2 of the first oxide transistor T4 are arranged in different layers. The first scan line Nscan-T4 is connected to the first sub-line ZL3-1 through a first connection node HD1, and is connected to the second sub-line ZL3-2 through a second connection node HD2. That is, the first sub-line ZL3-1 and the second sub-line ZL3-2 are connected to the first scan line Nscan-T4 through different connection nodes, and a voltage on the first sub-line ZL3-1 is same as a voltage on the second sub-line ZL3-2. In this way, an orthographic projection of the first sub-line ZL3-1 on the substrate 10 at least partially overlaps with an orthographic projection of the second sub-line ZL3-2 on the substrate 10, thereby saving wiring space.

Similarly, the gate electrode of the second oxide transistor T3 includes a third gate electrode GE3 and a fourth gate electrode GE4 arranged corresponding to each other. The third gate electrode GE3 and the first gate electrode GE1 are arranged in the same layer. The fourth gate electrode GE4 and the second gate electrode GE2 are arranged in the same layer. The fourth connection line ZL4 includes a third sub-line ZL4-1 and a fourth sub-line ZL4-2. The third sub-line ZL4-1 is connected between the second scan line Nscan-T3 and the third gate electrode GE3 of the second oxide transistor T3. The fourth sub-line ZL4-2 is connected between the second scan line Nscan-T3 and the fourth gate electrode GE4 of the second oxide transistor T3. The third gate electrode GE3 and the fourth gate electrode GE4 are arranged in different layers. An orthographic projection of the third gate electrode GE3 on the substrate 10 is within an orthographic projection of the fourth gate electrode GE4 on the substrate 10. The third sub-line ZL4-1 and the third gate electrode GE3 are arranged in the same layer. The fourth sub-line ZL4-2 and the fourth gate electrode GE4 are arranged in the same layer.

The second scan line Nscan-T3 and the third gate electrode GE3 and the fourth gate electrode GE4 of the second oxide transistor T3 are arranged in different layers. The second scan line Nscan-T3 is connected to one of the third sub-line ZL4-1 and the fourth sub-line ZL4-2 through a third connection node HD3. The present disclosure takes as an example that the second scan line Nscan-T3 is connected to the third sub-line ZL4-1 through the third connection node HD3. The third sub-line ZL4-1 is connected to the fourth sub-line ZL4-2 through a fourth connection node HD4. That is, the third sub-line ZL4-1 and the fourth sub-line ZL4-2 are connected to the second scan line Nscan-T3 through different connection nodes, and a voltage on the third sub-line ZL4-1 is same as a voltage on the fourth sub-line ZL4-2. In this way, an orthographic projection of the third sub-line ZL4-1 on the substrate 10 at least partially overlaps with an orthographic projection of the fourth sub-line ZL4-2 on the substrate 10, thereby saving wiring space.

It should be noted that “arranged in a same layer” described in the present disclosure is explained as follows. During a manufacturing process, a layer formed of a same material is patterned to obtain at least two different structures, so the at least two different structures are arranged in the same layer. For example, in the present disclosure, the first sub-line ZL3-1, the third sub-line ZL4-1, the first gate electrode GE1, and the third gate electrode GE3 are obtained by patterning a same conductive layer, so the first sub-line ZL3-1, the third sub-line ZL4-1, the first gate electrode GE1, and the third gate electrode GE3 are arranged in the same layer.

In another embodiment, the gate electrode of the first oxide transistor T4 includes the first gate electrode GE1 and the second gate electrode GE2 arranged corresponding to each other. The first gate electrode GE1 is electrically connected to the second gate electrode GE2. The third connection line ZL3 is electrically connected to one of the first gate electrode GE1 and the second gate electrode GE2. That is, the first gate electrode GE1 and the second gate electrode GE2 are electrically connected first, and then one of the first gate electrode GE1 and the second gate electrode GE2 is electrically connected to the first scan line Nscan-T4 through the third connection line ZL3. In this way, the number of the third connection lines ZL3 is reduced, thereby saving wiring space.

Similarly, the gate electrode of the second oxide transistor T3 includes the third gate electrode GE3 and the fourth gate electrode GE4 arranged corresponding to each other. The third gate electrode GE3 is electrically connected to the fourth gate electrode GE4. The fourth connection line ZL4 is electrically connected to one of the third gate electrode GE3 and the fourth gate electrode GE4. That is, the third gate electrode GE3 and the fourth gate electrode GE4 are electrically connected first, and then one of the third gate electrode GE3 and the fourth gate electrode GE4 is electrically connected to the second scan line Nscan-T3 through the fourth connection line ZL4. In this way, the number of the fourth connection lines ZL4 is reduced, thereby saving wiring space.

The following takes the first transistor T1 and the third transistor T3 in the sub-pixel SP as an example to describe a positional relationship of the first scan line Nscan-T4, the second scan line Nscan-T3, the first connection line ZL1, and the second connection line ZL2 in a layer structure of the array substrate 100.

Referring to FIG. 7 and FIG. 9, the array substrate 100 further includes the following layers.

A first semiconductor layer 20 is disposed on the substrate 10. The first semiconductor layer 20 includes an active layer AS of the first transistor T1. The first semiconductor layer 20 further includes active layers of the second transistor T2, the fifth transistor T5, the sixth transistor T6, the seventh transistor T7, and the eighth transistor T8.

A first metal layer 30 is disposed on a side of the first semiconductor layer 20 away from the substrate 10. The first metal layer 30 includes the gate electrode GE of the first transistor T1. Necessarily, the first metal layer 30 further includes the gate electrodes of the second transistor T2, the fifth transistor T5, the sixth transistor T6, the seventh transistor T7, and the eighth transistor T8.

A second metal layer 40 is disposed on a side of the first metal layer 30 away from the first semiconductor layer 20. The second metal layer 40 includes the second electrode 41 of the storage capacitor C1, the third gate electrode GE3 of the second oxide transistor T3, and the third sub-line ZL4-1 connected to the third gate electrode GE3. Necessarily, the second metal layer 40 further includes the first gate electrode GE1 of the first oxide transistor T4 and the first sub-line ZL3-1 connected to the first gate electrode GE1.

A second semiconductor layer 50 is disposed on a side of the second metal layer 40 away from the first metal layer 30. The second semiconductor layer 50 includes an active layer OX of the second oxide transistor T3, the first connection line ZL1, and the second connection line ZL2. It should be noted that both the first connection line ZL1 and the second connection line ZL2 may be formed by conducting the second semiconductor layer 50. FIG. 9 schematically shows the second connection line ZL2. Necessarily, the second semiconductor layer 50 further includes an active layer of the first oxide transistor T4.

A third metal layer 60 is disposed on a side of the second semiconductor layer 50 away from the second metal layer 40. The third metal layer 60 includes the fourth gate electrode GE4 of the second oxide transistor T3 and the fourth sub-line ZL4-2 connected to the fourth gate electrode GE4. That is, the two gate electrodes of the second oxide transistor T3 are respectively formed in the third metal layer 60 and the second metal layer 40. Necessarily, the third metal layer 60 further includes the second gate electrode GE2 of the first oxide transistor T4 and the second sub-line ZL3-2 connected to the second gate electrode GE2. That is, the two gate electrodes of the first oxide transistor T4 are respectively formed in the third metal layer 60 and the second metal layer 40.

A fourth metal layer 70 is disposed on a side of the third metal layer 60 away from the second semiconductor layer 50. The fourth metal layer 70 includes the first scan line Nscan-T4, the second scan line Nscan-T3, the drain electrode D1 of the first transistor T1, and the drain electrode D3 of the second oxide transistor T3. FIG. 9 schematically shows the second scan line Nscan-T3.

A fifth metal layer 80 is disposed on a side of the fourth metal layer 70 away from the third metal layer 60. The fifth metal layer 80 includes the first data line Data1 and the first power line VDD. FIG. 9 schematically shows the first data line Data1.

The first metal layer 30, the second metal layer 40, the third metal layer 60, the fourth metal layer 70, and the fifth metal layer 80 may be made of one or more of metals such as molybdenum (Mo), copper (Cu), aluminum (Al), and titanium (Ti), or one or more of alloys formed by any combination of the above metals, or other suitable material. In addition, the first metal layer 30, the second metal layer 40, the third metal layer 60, the fourth metal layer 70, and the fifth metal layer 80 may also have a single-layer structure or a multi-layer structure. The first semiconductor layer 20 may be made of low-temperature polysilicon or the like. The second semiconductor layer 50 may have a single-layer structure or a multi-layer structure made of indium gallium zinc oxide (IGZO), indium tin zinc oxide (ITZO), or indium gallium zinc tin oxide (IGZTO).

Optionally, the array substrate 100 may further include a light-shielding layer 90 disposed between the substrate 10 and the first semiconductor layer 20. The light-shielding layer 90 includes a light-shielding electrode 91 disposed corresponding to the active layer AS of the first transistor T1 to shield the active layer AS of the first transistor T1 from light. The substrate 10 may be a rigid substrate or a flexible substrate. When the substrate 10 is a rigid substrate, it may be a glass substrate, a quartz substrate, a silicon wafer, or other rigid substrate. When the substrate 10 is a flexible substrate, it may be a polyimide (PI) film, an ultra-thin glass film, or other flexible substrate. The present disclosure takes as an example that the substrate 10 is a double-layer polyimide film. The light-shielding layer 90 is made of a material with a light-shielding function such as a light-shielding metal.

Necessarily, the array substrate 100 further includes a plurality of insulating layers disposed between the metal layers and the semiconductor layers. For example, the insulating layers include a first buffer layer 11 disposed between the substrate 10 and the light-shielding layer 90, a second buffer layer disposed between the light-shielding layer 90 and the first semiconductor layer 20, a first gate insulating layer 13 disposed between the first semiconductor layer 20 and the first metal layer 30, a second gate insulating layer 14 disposed between the first metal layer 30 and the second metal layer 40, a third gate insulating layer 15 disposed between the second metal layer 40 and the second semiconductor layer 50, a fourth gate insulating layer 16 disposed between the second semiconductor layer 50 and the third metal layer 60, an interlayer insulating layer 17 disposed between the third metal layer 60 and the fourth metal layer 70, a first planarization layer 18 disposed between the fourth metal layer 70 and the fifth metal layer 80, and a second planarization layer 19 covering the fifth metal layer 80. The first buffer layer 11, the second buffer layer 12, the first gate insulating layer 13, the second gate insulating layer 14, the third gate insulating layer 15, the fourth gate insulating layer 16, and the interlayer insulating layer 17 are made of an inorganic material such as silicon oxide and silicon nitride. The first planarization layer 18 and the second planarization layer 19 are made of an organic material such as organic photoresist.

Based on the same inventive concept, the present disclosure further provides a display panel, which includes the array substrate 100 of one of the aforementioned embodiments. The display panel may be an organic light-emitting diode display panel and the like.

According to the above embodiment, it can be seen that:

In the array substrate and the display panel of the present disclosure, the array substrate includes a substrate and a plurality of sub-pixels arranged in an array on the substrate. Each of the sub-pixels comprises a first transistor, and a first oxide transistor and a second oxide transistor connected to the first transistor. The array substrate further comprises: a first connection line connected between the drain electrode of the first oxide transistor and the gate electrode of the first transistor, a second connection line connected between the drain electrode of the first oxide transistor and the source electrode of the second oxide transistor, a first scan line connected to a gate electrode of the first oxide transistor, and a second scan line connected to a gate electrode of the second oxide transistor. An orthographic projection of the first scan line on the substrate is separated from an orthographic projection of the first connection line and the second connection line on the substrate, and an orthographic projection of the second scan line on the substrate is separated from the orthographic projection of the first connection line and the second connection line on the substrate. Since the first scan line and the second scan line do not overlap with a first connection line and a second connection line, coupling capacitances between the first scan line, the second scan line, the first connection line, and the second connection line is reduced, thereby solving the technical problem of serious lateral crosstalk in current LTPO display panels.

In the above embodiments, the descriptions of each embodiment have their own emphasis, and the part that is not detailed in a certain embodiment may be referred to the relevant descriptions of other embodiments.

The embodiments of the present disclosure are described in detail above. The present disclosure uses specific examples to describe principles and embodiments of the present application. The above description of the embodiments is only for helping to understand the technical solutions of the present disclosure and its core ideas. It should be understood by those skilled in the art that they can modify the technical solutions recited in the foregoing embodiments, or replace some of technical features in the foregoing embodiments with equivalents. These modifications or replacements do not cause essence of corresponding technical solutions to depart from the scope of the technical solutions of the embodiments of the present disclosure.

1. An array substrate, comprising a substrate and a plurality of sub-pixels arranged in an array on the substrate, wherein each of the sub-pixels comprises a first transistor, and a first oxide transistor and a second oxide transistor connected to the first transistor; a drain electrode of the first oxide transistor is connected to a gate electrode of the first transistor, and is connected to a source electrode of the second oxide transistor; a drain electrode of the second oxide transistor is connected to a drain electrode of the first transistor; and
the array substrate further comprises:
a first connection line connected between the drain electrode of the first oxide transistor and the gate electrode of the first transistor;
a second connection line connected between the drain electrode of the first oxide transistor and the source electrode of the second oxide transistor;
a first scan line connected to a gate electrode of the first oxide transistor; and
a second scan line connected to a gate electrode of the second oxide transistor;
wherein an orthographic projection of the first scan line on the substrate is separated from an orthographic projection of the first connection line and the second connection line on the substrate, and an orthographic projection of the second scan line on the substrate is separated from the orthographic projection of the first connection line and the second connection line on the substrate.

2. The array substrate according to claim 1, wherein the first scan line and the second scan line extend in a first direction and are spaced apart in a second direction, the first direction is different from the second direction, and the first connection line extends in the second direction; and
the first scan line is located on a side of the first connection line away from the first transistor or the first oxide transistor, or the second scan line is located on a side of the first connection line away from the first transistor or the first oxide transistor.

3. The array substrate according to claim 2, wherein in the second direction, the first transistor and the first oxide transistor are respectively located at both ends of the first connection line, and the first scan line and the second scan line are located on the side of the first connection line away from the first transistor.

4. The array substrate according to claim 3, wherein in the second direction, the second oxide transistor is located between the first transistor and the first oxide transistor, the second connection line is connected between the first oxide transistor and the second oxide transistor, and the first scan line is located on a side of the second scan line away from the second connection line.

5. The array substrate according to claim 2, wherein the array substrate further includes a third connection line and a fourth connection line, the third connection line and the fourth connection line extend in the second direction, the third connection line is connected between the first scan line and the gate electrode of the first oxide transistor, the fourth connection line is connected between the second scan line and the gate electrode of the second oxide transistor, an orthographic projection of the third connection line on the substrate is separated from the orthographic projection of the first connection line and the second connection line on the substrate, and an orthographic projection of the fourth connection line on the substrate is separated from the orthographic projection of the first connection line and the second connection line on the substrate.

6. The array substrate according to claim 5, wherein the gate electrode of the first oxide transistor includes the first gate electrode and the second gate electrode arranged corresponding to each other, the first gate electrode is electrically connected to the second gate electrode, and the third connection line is electrically connected to one of the first gate electrode and the second gate electrode; and
the gate electrode of the second oxide transistor includes the third gate electrode and the fourth gate electrode arranged corresponding to each other, the third gate electrode is electrically connected to the fourth gate electrode, and the fourth connection line is electrically connected to one of the third gate electrode and the fourth gate electrode.

7. The array substrate according to claim 5, wherein the gate electrode of the first oxide transistor includes a first gate electrode and a second gate electrode arranged corresponding to each other, the third connection line includes a first sub-line and a second sub-line, the first sub-line is connected between the first scan line and the first gate electrode, and the second sub-line is connected between the first scan line and the second gate electrode; and
the gate electrode of the second oxide transistor includes a third gate electrode and a fourth gate electrode arranged corresponding to each other, the fourth connection line includes a third sub-line and a fourth sub-line, the third sub-line is connected between the second scan line and the third gate electrode, and the fourth sub-line is connected between the second scan line and the fourth gate electrode.

8. The array substrate according to claim 7, wherein the first gate electrode and the third gate electrode are arranged in the same layer, the second gate electrode and the fourth gate electrode are arranged in the same layer, the first sub-line and the first gate electrode are arranged in the same layer, the second sub-line and the second gate electrode are arranged in the same layer, the third sub-line and the third gate electrode are arranged in the same layer, the fourth sub-line and the fourth gate electrode are arranged in the same layer.

9. The array substrate according to claim 8, wherein the first scan line, the first gate electrode, and the second gate electrode are arranged in different layers, the second scan line, the third gate electrode, and the fourth gate electrode are arranged in different layers, the first scan line is connected to the first sub-line through a first connection node and is connected to the second sub-line through a second connection node, the second scan line is connected to one of the third sub-line and the fourth sub-line through a third connection node, the third sub-line is connected to the fourth sub-line through a fourth connection node.

10. The array substrate of claim 7, wherein the orthotropic projection of the first sub-line on the substrate overlaps at least partially with the orthotropic projection of the second sub-line on the substrate, and the orthotropic projection of the third sub-line on the substrate overlaps at least partially with the orthotropic projection of the fourth sub-line on the substrate.

11. The array substrate of claim 1, wherein each subpixel further comprises a second transistor, a third transistor, a fourth transistor, a fifth transistor, a sixth transistor, a seventh transistor, an eighth transistor, a storage capacitor and a compensation capacitor, wherein the third transistor and the fourth transistor are oxide transistors, and the first transistor, the second transistor, the third transistor, the fourth transistor, the fifth transistor, the sixth transistor, the seventh transistor and the eighth transistor are polycrystalline silicon transistors, the fourth transistors are first oxide transistors, and the third transistors are second oxide transistors;
wherein a drain of the fourth transistor is connected with a first electrode plate of the storage capacitor and a first electrode plate of the compensation capacitance, the first electrode plate of the storage capacitor is integrally arranged with the gate of the first transistor, a second electrode plate of the compensation capacitance is connected with a gate of the second transistor, a second electrode plate of the storage capacitor is connected with a source of the fifth transistor, a drain of the fifth transistor is connected with a source of the first transistor, a drain of the first transistor is connected with a drain of the third transistor and a source of the sixth transistor, and a drain of the sixth transistor is connected with a drain of the seventh transistor, a source of the first transistor, a drain of the second transistor and a drain of the fifth transistor are all connected with a drain of the eighth transistor.

12. The array substrate of claim 1, further comprising:
a first semiconductor layer, arranged on the substrate and comprising an active layer of the first transistor;
a first metal layer, arranged on one side of the first semiconductor layer far away from the substrate, and the first metal layer comprising a gate of the first transistor;
a second metal layer, arranged on one side of the first metal layer far away from the first semiconductor layer;
a second semiconductor layer, arranged on one side of the second metal layer far away from the first metal layer, and the second semiconductor layer comprising an active layer of the first oxide transistor, an active layer of the second oxide transistor, a first connecting wire and a second connecting line;
a third metal layer, arranged on one side of the second semiconductor layer far away from the second metal layer, and a gate of the first oxide transistor and a gate of the second oxide transistor are formed in the third metal layer and the second metal layer;
a fourth metal layer, arranged on one side of the third metal layer far away from the second semiconductor layer, and comprising the first scan line and the second scan line.

13. A display panel, comprising an array substrate, the array substrate comprising a substrate and a plurality of sub-pixels arranged in an array on the substrate, wherein each of the sub-pixels comprises a first transistor, and a first oxide transistor and a second oxide transistor connected to the first transistor; a drain electrode of the first oxide transistor is connected to a gate electrode of the first transistor, and is connected to a source electrode of the second oxide transistor; a drain electrode of the second oxide transistor is connected to a drain electrode of the first transistor;
the array substrate further comprises:
a first connection line connected between the drain electrode of the first oxide transistor and the gate electrode of the first transistor;
a second connection line connected between the drain electrode of the first oxide transistor and the source electrode of the second oxide transistor;
a first scan line connected to a gate electrode of the first oxide transistor; and
a second scan line connected to a gate electrode of the second oxide transistor;
wherein an orthographic projection of the first scan line on the substrate is separated from an orthographic projection of the first connection line and the second connection line on the substrate, and an orthographic projection of the second scan line on the substrate is separated from the orthographic projection of the first connection line and the second connection line on the substrate.

14. The array substrate according to claim 13, wherein the first scan line and the second scan line extend in a first direction and are spaced apart in a second direction, the first direction is different from the second direction, and the first connection line extends in the second direction; and
the first scan line is located on a side of the first connection line away from the first transistor or the first oxide transistor, or the second scan line is located on a side of the first connection line away from the first transistor or the first oxide transistor.

15. The array substrate according to claim 14, wherein in the second direction, the first transistor and the first oxide transistor are respectively located at both ends of the first connection line, and the first scan line and the second scan line are located on the side of the first connection line away from the first transistor.

16. The array substrate according to claim 15, wherein in the second direction, the second oxide transistor is located between the first transistor and the first oxide transistor, the second connection line is connected between the first oxide transistor and the second oxide transistor, and the first scan line is located on a side of the second scan line away from the second connection line.

17. The array substrate according to claim 14, wherein the array substrate further includes a third connection line and a fourth connection line, the third connection line and the fourth connection line extend in the second direction, the third connection line is connected between the first scan line and the gate electrode of the first oxide transistor, the fourth connection line is connected between the second scan line and the gate electrode of the second oxide transistor, an orthographic projection of the third connection line on the substrate is separated from the orthographic projection of the first connection line and the second connection line on the substrate, and an orthographic projection of the fourth connection line on the substrate is separated from the orthographic projection of the first connection line and the second connection line on the substrate.

18. The array substrate according to claim 17, wherein the gate electrode of the first oxide transistor includes the first gate electrode and the second gate electrode arranged corresponding to each other, the first gate electrode is electrically connected to the second gate electrode, and the third connection line is electrically connected to one of the first gate electrode and the second gate electrode; and
the gate electrode of the second oxide transistor includes the third gate electrode and the fourth gate electrode arranged corresponding to each other, the third gate electrode is electrically connected to the fourth gate electrode, and the fourth connection line is electrically connected to one of the third gate electrode and the fourth gate electrode.

19. The array substrate according to claim 17, wherein the gate electrode of the first oxide transistor includes a first gate electrode and a second gate electrode arranged corresponding to each other, the third connection line includes a first sub-line and a second sub-line, the first sub-line is connected between the first scan line and the first gate electrode, and the second sub-line is connected between the first scan line and the second gate electrode; and
the gate electrode of the second oxide transistor includes a third gate electrode and a fourth gate electrode arranged corresponding to each other, the fourth connection line includes a third sub-line and a fourth sub-line, the third sub-line is connected between the second scan line and the third gate electrode, and the fourth sub-line is connected between the second scan line and the fourth gate electrode.

20. The array substrate according to claim 19, wherein the first gate electrode and the third gate electrode are arranged in the same layer, the second gate electrode and the fourth gate electrode are arranged in the same layer, the first sub-line and the first gate electrode are arranged in the same layer, the second sub-line and the second gate electrode are arranged in the same layer, the third sub-line and the third gate electrode are arranged in the same layer, the fourth sub-line and the fourth gate electrode are arranged in the same layer.
